(19) United States
(12) Patent Application Publication
(10) Pub. No.: US 2022/0171353 A1
(43) Pub. Date: Jun. 2, 2022

(54) DIFFERENTIABLE MACHINES FOR PHYSICAL SYSTEMS

(71) Applicant: DEEP FOREST SCIENCES, INC., Palo Alto, CA (US)

(72) Inventor: BHARATH RAMSUNDAR, Palo Alto, CA (US)

(73) Assignee: DEEP FOREST SCIENCES, INC., Palo Alto, CA (US)

(21) Appl. No.: 17/541,202

(22) Filed: Dec. 2, 2021

Related U.S. Application Data
(60) Provisional application No. 63/120,685, filed on Dec. 2, 2020.

(51) Int. Cl. G05B 15/02

(52) U.S. Cl. CPC G05B 15/02

(57) ABSTRACT

Apparatuses, systems, computer program products, and methods are disclosed for differentiable machines for physical systems. A hardware server device is configured to determine a plurality of differentiable models each representing a component of a physical system. A hardware server device is configured to combine a plurality of differentiable models using an integration layer so that the integration layer and the combined differentiable models form a differentiable machine representing a physical system. A hardware server device is configured to deploy a differentiable machine for an instance of a physical system.

### CROSS-REFERENCES TO RELATED APPLICATIONS

This application claims the benefit of U.S. Provisional Patent Application No. 63/120,685 entitled “DIFFERENTIABLE MACHINES FOR COMPOSABLE AND EFFICIENT END-TO-END SIMULATION AND CONTROL OF PHYSICAL DEVICES” and filed on Dec. 2, 2020, for Bharath Ramsundar, which is incorporated herein by reference in its entirety for all purposes.

### FIELD

This invention relates to physical systems and more particularly relates to simulating and/or controlling physical systems using differentiable machines.

### BACKGROUND

Physical systems are often complex entities, with many interacting parts and varied purposes. While industrial machines operate under known physics, they may do so in complex combinations which may not be feasible to model effectively. For example, a device may make use of mechanical gears, electrochemical batteries, magnetic fields, optical amplification, biological enzymes, and more to achieve a purpose. The complexity of physical systems, including living organisms, can make modeling, debugging, and/or troubleshooting a physical system difficult.

### SUMMARY

Apparatuses, systems, computer program products, and methods are disclosed for differentiable machines for physical systems. An apparatus, in one embodiment, includes a hardware server device. A hardware server device, in some embodiments, is configured to determine a plurality of differentiable models each representing a component of a physical system. In a further embodiment, a hardware server device is configured to combine a plurality of differentiable models using an integration layer so that the integration layer and the combined differentiable models form a differentiable machine representing a physical system. A hardware server, in certain embodiments, is configured to deploy a differentiable machine for an instance of the physical system

A computer program product, in some embodiments, comprises executable program code stored on a non-transitory computer readable storage medium, the executable program code executable by a processor to perform operations for differentiable machines for physical systems. An operation, in one embodiment, includes determining a plurality of differentiable models each representing a component of a physical system. In certain embodiments, an operation includes combining a plurality of differentiable models using an integration layer so that the integration layer and the combined differentiable models form a differentiable machine representing a physical system. An operation, in a further embodiment, includes deploying a differentiable machine for an instance of a physical system.

A method, in one embodiment, includes determining a plurality of differentiable models each representing a component of a physical system. A method, in some embodiments, includes combining a plurality of differentiable models using an integration layer so that the integration layer and the combined differentiable models form a differentiable machine representing a physical system. A method, in certain embodiments, includes deploying a differentiable machine for an instance of a physical system.

Other apparatuses are disclosed for differentiable machines for physical systems. In one embodiment, an apparatus includes means for determining a plurality of differentiable models each representing a component of a physical system. An apparatus, in certain embodiments, includes means for combining a plurality of differentiable models using an integration layer so that the integration layer and the combined differentiable models form a differentiable machine representing a physical system. In some embodiments, an apparatus includes means for deploying a differentiable machine for an instance of a physical system.

### BRIEF DESCRIPTION OF THE DRAWINGS

In order that the advantages of the invention will be readily understood, a more particular description of the invention briefly described above will be rendered by reference to specific embodiments that are illustrated in the appended drawings. Understanding that these drawings depict only typical embodiments of the invention and are not therefore to be considered to be limiting of its scope, the invention will be described and explained with additional specificity and detail through the use of the accompanying drawings, in which:

FIG. 1 is a schematic block diagram illustrating one embodiment of a system for a differentiable machine for a physical system;

FIG. 2A is a schematic block diagram illustrating one embodiment of a differentiable machine;

FIG. 2B is a schematic block diagram illustrating another embodiment of a differentiable machine;

FIG. 2C is a schematic block diagram illustrating a certain embodiment of a differentiable machine;

FIG. 2D is a schematic block diagram illustrating a further embodiment of a differentiable machine;

FIG. 3 is a schematic block diagram illustrating one embodiment of a differentiable group;

FIG. 4 is a schematic flow chart diagram illustrating one embodiment of a method for a differentiable machine for a physical system;

FIG. 5 is a schematic flow chart diagram illustrating another embodiment of a method for a differentiable machine for a physical system;

FIG. 6 is a schematic flow chart diagram illustrating a further embodiment of a method for a differentiable machine for a physical system; and

FIG. 7 is a schematic flow chart diagram illustrating a certain embodiment of a method for a differentiable machine for a physical system.

### DETAILED DESCRIPTION

Reference throughout this specification to “one embodiment,” “an embodiment,” or similar language means that a particular feature, structure, or characteristic described in connection with the embodiment is included in at least one embodiment. Thus, appearances of the phrases “in one embodiment,” “in an embodiment,” and similar language throughout this specification may, but do not necessarily, all refer to the same embodiment, but mean “one or more but not all embodiments” unless expressly specified otherwise. The terms “including,” “comprising,” “having,” and variations thereof mean “including but not limited to” unless expressly specified otherwise. An enumerated listing of items does not imply that any or all of the items are mutually exclusive and/or mutually inclusive, unless expressly specified otherwise. The terms “a,” “an,” and “the” also refer to “one or more” unless expressly specified otherwise.

Furthermore, the described features, advantages, and characteristics of the embodiments may be combined in any suitable manner. One skilled in the relevant art will recognize that the embodiments may be practiced without one or more of the specific features or advantages of a particular embodiment. In other instances, additional features and advantages may be recognized in certain embodiments that may not be present in all embodiments.

These features and advantages of the embodiments will become more fully apparent from the following description and appended claims, or may be learned by the practice of embodiments as set forth hereinafter. As will be appreciated by one skilled in the art, aspects of the present invention may be embodied as a system, method, and/or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module,” or “system.” Furthermore, aspects of the present invention may take the form of a computer program product embodied in one or more computer readable medium(s) having program code embodied thereon.

Many of the functional units described in this specification have been labeled as modules, in order to more particularly emphasize their implementation independence. For example, a module may be implemented as a hardware circuit comprising custom VLSI circuits or gate arrays, off-the-shelf semiconductors such as logic chips, transistors, or other discrete components. A module may also be implemented in programmable hardware devices such as field programmable gate arrays, programmable array logic, programmable logic devices or the like.

Modules may also be implemented in software for execution by various types of processors. An identified module of program code may, for instance, comprise one or more physical or logical blocks of computer instructions which may, for instance, be organized as an object, procedure, or function. Nevertheless, the executables of an identified module need not be physically located together, but may comprise disparate instructions stored in different locations which, when joined logically together, comprise the module and achieve the stated purpose for the module.

Indeed, a module of program code may be a single instruction, or many instructions, and may even be distributed over several different code segments, among different programs, and across several memory devices. Similarly, operational data may be identified and illustrated herein within modules, and may be embodied in any suitable form and organized within any suitable type of data structure. The operational data may be collected as a single data set, or may be distributed over different locations including over different storage devices, and may exist, at least partially, merely as electronic signals on a system or network. Where a module or portions of a module are implemented in software, the program code may be stored and/or propagated on in one or more computer readable medium(s).

The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (“RAM”), a read-only memory (“ROM”), an erasable programmable read-only memory (“EPROM” or Flash memory), a static random access memory (“SRAM”), a portable compact disc read-only memory (“CD-ROM”), a digital versatile disk (“DVD”), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The schematic flowchart diagrams and/or schematic block diagrams in the Figures illustrate the architecture, functionality, and operation of possible implementations of apparatuses, systems, methods and computer program products according to various embodiments of the present invention. In this regard, each block in the schematic flowchart diagrams and/or schematic block diagrams may represent a module, segment, or portion of code, which comprises one or more executable instructions of the program code for implementing the specified logical function(s).

It should also be noted that, in some alternative implementations, the functions noted in the block may occur out of the order noted in the Figures. For example, two blocks shown in succession may, in fact, be executed substantially concurrently, or the blocks may sometimes be executed in the reverse order, depending upon the functionality involved. Other steps and methods may be conceived that are equivalent in function, logic, or effect to one or more blocks, or portions thereof, of the illustrated Figures.

Although various arrow types and line types may be employed in the flowchart and/or block diagrams, they are understood not to limit the scope of the corresponding embodiments. Indeed, some arrows or other connectors may be used to indicate only the logical flow of the depicted embodiment. For instance, an arrow may indicate a waiting or monitoring period of unspecified duration between enumerated steps of the depicted embodiment. It will also be noted that each block of the block diagrams and/or flowchart diagrams, and combinations of blocks in the block diagrams and/or flowchart diagrams, can be implemented by special purpose hardware-based systems that perform the specified functions or acts, or combinations of special purpose hardware and program code.

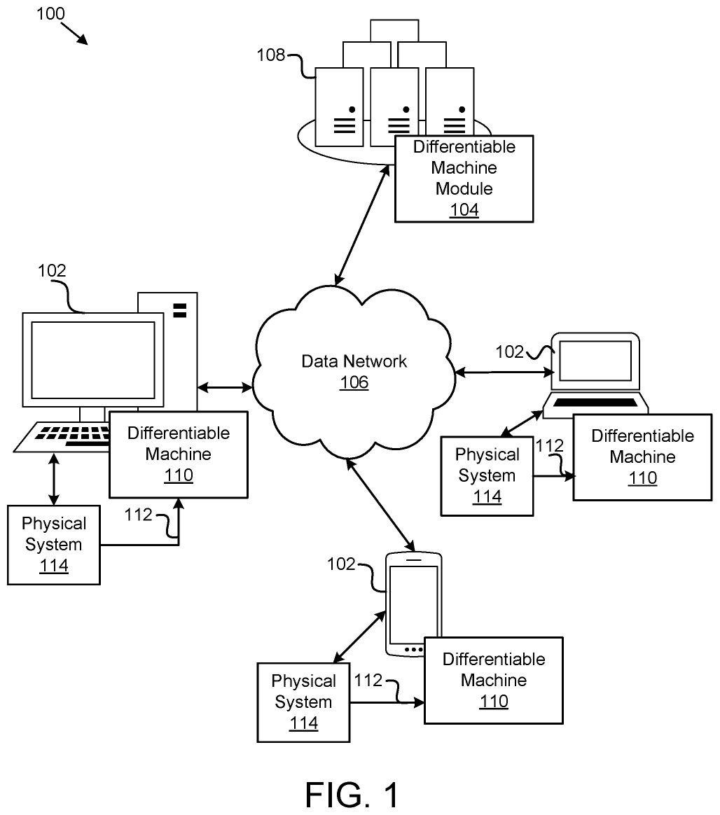

FIG. 1 is a schematic block diagram illustrating one embodiment of a system 100 for a differentiable machine 110 for a physical system 114. In one embodiment, the system 100 includes one or more hardware computing devices 102, one or more differentiable machine modules 104, one or more data networks 106, one or more hardware server devices 108, one or more differentiable machines 110, one or more outputs 112, and one or more physical systems 114. In certain embodiments, even though a specific number of hardware computing devices 102, differentiable machine modules 104, data networks 106, hardware server devices 108, differentiable machines 110, outputs 112, and/or physical systems 114 are depicted in FIG. 1, one of skill in the art will recognize, in light of this disclosure, that any number of hardware computing devices 102, differentiable machine modules 104, data networks 106, hardware server devices 108, differentiable machines 110, outputs 112, and/or physical systems 114 may be included in the system 100.

Some models of a physical system 114 may elide some or all of the underlying complexity and may therefore have limited use for modelling the real-world behavior of a physical system 114. For example, a simple circuit model of a physical system comprising a battery may suffice for back-of-the-envelope modelling but may not suffice to model the behavior of a live battery. Simulation techniques, in some embodiments, may serve as stopgaps allowing more complex models of physical systems 114 to be built, but these simulations may be limited by computational cost, approximation error, or the like. Similarly, some generic machine learning models may be data inefficient and may require many physical measurements or other data to train.

The difficulty of modeling physical systems 114, in various embodiments, may make these methods of debugging a physical system 114 burdensome or impossible, often requiring repeated rounds of device experimentation and/or manual tuning of simulation models to match physical characteristics of a given physical system 114. The differentiable machine module 104, in certain embodiments, may generate differentiable machines 110 comprising efficient, end-to-end differentiable models of complete physical systems 114 that may be used to tightly model and/or control behavior of a physical system 114 (e.g., an input, an output, or the like).

Unlike a simple analytical model, in some embodiments, a differentiable machine 110 may be arbitrarily complex and may model physical phenomena associated with a physical system 114 and/or a component of a physical system 114 in great detail. Unlike a simulation, in certain embodiments, a differentiable machine 110 may use learned approximations that can reduce computation time and/or learn to reduce errors by training the differentiable machine 110 to model actual, physical, experimental outputs 112 from a specific instance or version of a physical system 114.

The differentiable machine module 104 may generate and/or customize differentiable machines 110 for a broad range of physical systems 114. A differentiable machine 110, in certain embodiments, may comprise multiple differentiable models each associated with a component of a physical system 114, and each differentiable over their domains (e.g., a derivative exists at each point in the domains), so that the entire differentiable machine 110 is differentiable from end-to-end (e.g., from input to output, or the like). In this manner, in one embodiment, the differentiable machine 110 may take a derivative of a differentiable machine 110, including each of the differentiable models, based on the chain rule, in order to tune the entire differentiable machine 110 together (e.g., determine weights or other parameters), however complex and whatever the number of the underlying differentiable models.

For example, initial values for weights or other parameters of a differentiable machine 110 may be unknown, set to defaults, estimated, or the like by the differentiable machine module 104, and the differentiable machine module 104 may train and/or tune the differentiable machine 110 by adjusting the weights or other parameters based on the real, actual, experimental measurements or other outputs 112 determined from a specific, actual, physical instance of the physical system 114 (e.g., so that an output of the differentiable machine 110 more closely matches and/or predicts an output 112 of the physical system 114, or the like).

Unlike the differentiable machine 110 and its differentiable models, there may be no convenient or even possible way to tune certain other physics models of equations to the behavioral characteristics of a real physical system 114. Further, when attempting to use a simulator to model a physical system 114, the simulator may have some manual configuration settings, but a simulator typically cannot be matched to a specific physical system 114, and machine noise quickly becomes nonlinear so it may not be clear how errors in one stage of the physical system 114 may propagate to or affect the next stage of the physical system 114 using a simulator. A differentiable machine 110, however, in certain embodiments, may adjust itself through its underlying differentiable models and balance off errors across the differentiable models and/or an integration layer to create an accurate model that matches the real physics of the physical system 114.

Other machine learning models that attempt to map device inputs to outputs, without attempting to model physics of the physical system, may significantly increase the data requirements to tune the machine learning model, which may also be less accurate. In contrast, a differentiable machine 110, given its strong physical prior, in some embodiments may be tunable with minimal amounts of data (e.g., the output 112 of the physical system 114, or the like).

In general, a differentiable machine module 104 (e.g., executing on a hardware server device 108 or the like) may be configured to determine components of a physical system 114, determine differentiable models representing the components, combine the differentiable models using an integration layer to form a differentiable machine 110, and to deploy the differentiable machine 110 to a specific instance of a physical system 114 (e.g., to a hardware computing device 102 in communication with the specific instance of the physical system 114) where the differentiable machine 110 may be tuned based on output 112 of the instance of the physical system 114, or the like.

The one or more hardware server devices 108, in one embodiment, hosts or otherwise stores and/or executes one or more differentiable machine modules 104. A hardware server device 108, as used herein, comprises a hardware computing device (e.g., including a processor and a volatile and/or non-volatile memory, or the like) that generates one or more differentiable machines 110. A hardware server device 108 may be embodied as a desktop computer, a laptop computer, a tablet computer, a smart phone, an embedded controller or other system, a mobile device, a tablet device, a blade server, a mainframe server, a tower server, a rack server, a cloud server, or another computing device comprising a processor (e.g., a central processing unit (“CPU”), a processor core, a field programmable gate array (“FPGA”) or other programmable logic, an application specific integrated circuit (“ASIC”), a controller, a microcontroller, and/or another semiconductor integrated circuit device), a volatile memory, and/or a non-volatile storage medium. The one or more hardware server devices 108 may be configured as web servers, application servers, FTP servers, data servers, file servers, virtual servers, or the like. The one or more hardware server devices 108 may be communicatively coupled (e.g., networked) over a data network 106 to one or more hardware computing devices 102, may be integrated with one or more hardware computing devices 102, and/or may otherwise be in communication with one or more hardware computing devices 102.

The hardware computing devices 102, in various embodiments, may include one or more of a desktop computer, a laptop computer, a tablet computer, a smart phone, a smart speaker, a set-top box, a gaming console, a smart TV, a smart watch, a fitness band or other wearable activity tracking device, an optical head-mounted display (e.g., a virtual reality headset, smart glasses, or the like), a High-Definition Multimedia Interface (“HDMI”) or other electronic display dongle, a personal digital assistant, a digital camera, a video camera, a hardware server device 108, or another computing device comprising a processor, a volatile memory, and/or a non-volatile storage medium.

In certain embodiments, the hardware computing devices 102 are communicatively coupled to one or more other hardware computing devices 102, to one or more hardware server devices 108, and/or to one or more physical systems 114 over a data network 106, described below. The hardware computing devices 102, in a further embodiment, may include processors, processor cores, or the like that are configured to execute various programs, program code, applications, instructions, functions, or the like. The hardware computing devices 102 may include executable code, functions, instructions, operating systems, or the like for performing various operations for a differentiable machine 110, as described in greater detail below.

The differentiable machine module 104, including one or more sub-modules or other components, may be located on one or more hardware computing devices 102 in the system 100, one or more hardware server devices 108, one or more network devices, or the like. In various embodiments, the differentiable machine module 104 may be embodied as a hardware appliance that can be installed or deployed on a hardware computing device 102, on a hardware server device 108, or elsewhere on the data network 106. In certain embodiments, the differentiable machine module 104 may include a hardware device such as a secure hardware dongle or other hardware appliance device (e.g., a set-top box, a network appliance, or the like) that attaches to a device such as a laptop computer, a hardware server device 108, a tablet computer, a smart phone, a security system, or the like, either by a wired connection (e.g., a universal serial bus (“USB”) connection) or a wireless connection (e.g., Bluetooth®, Wi-Fi, near-field communication (“NFC”), or the like); that attaches to an electronic display device (e.g., a television or monitor using an HDMI port, a DisplayPort port, a Mini DisplayPort port, VGA port, DVI port, or the like); or the like. A hardware appliance of the differentiable machine module 104 may include a power interface, a wired and/or wireless network interface, a graphical interface that attaches to an electronic display device, and/or a semiconductor integrated circuit device, configured to perform the functions described herein with regard to the differentiable machine module 104 and/or a differentiable machine 110.

The differentiable machine module 104, in such an embodiment, may include a semiconductor integrated circuit device (e.g., one or more chips, die, or other discrete logic hardware), or the like, such as a field-programmable gate array (“FPGA”) or other programmable logic, firmware for an FPGA or other programmable logic, microcode for execution on a microcontroller, an application-specific integrated circuit (“ASIC”), a processor, a processor core, or the like. In one embodiment, the differentiable machine module 104 may be mounted on a printed circuit board with one or more electrical lines or connections (e.g., to volatile memory, a non-volatile storage medium, a network interface, a peripheral device, a graphical/display interface, or the like). The hardware appliance may include one or more pins, pads, or other electrical connections configured to send and receive data (e.g., in communication with one or more electrical lines of a printed circuit board or the like), and one or more hardware circuits and/or other electrical circuits configured to perform various functions of the differentiable machine module 104 and/or a differentiable machine 110.

The semiconductor integrated circuit device or other hardware appliance of the differentiable machine module 104 and/or a differentiable machine 110, in certain embodiments, includes and/or is communicatively coupled to one or more volatile memory media, which may include but is not limited to random access memory (“RAM”), dynamic RAM (“DRAM”), cache, or the like. In one embodiment, the semiconductor integrated circuit device or other hardware appliance of the differentiable machine module 104 includes and/or is communicatively coupled to one or more non-volatile memory media, which may include but is not limited to: NAND flash memory, NOR flash memory, nano random access memory (nano RAM or NRAM), nanocrystal wire-based memory, silicon-oxide based sub-10 nanometer process memory, graphene memory, Silicon-Oxide-Nitride-Oxide-Silicon (“SONOS”), resistive RAM (“RRAM”), programmable metallization cell (“PMC”), conductive-bridging RAM (“CBRAM”), magneto-resistive RAM (“MRAM”), dynamic RAM (“DRAM”), phase change RAM (“PRAM” or “PCM”), magnetic storage media (e.g., hard disk, tape), optical storage media, or the like.

The data network 106, in one embodiment, includes a digital communication channel that transmits digital communications. The data network 106 may be at least partially wired, such as an Ethernet network, a USB or other serial connection, or the like. The data network 106 may include a wireless network, such as a wireless cellular network, a local wireless network such as a Wi-Fi network, a Bluetooth® network, a near-field communication (“NFC”) network, an ad hoc network, or the like. The data network 106 may include a wide area network (“WAN”), a storage area network (“SAN”), a local area network (LAN), an optical fiber network, the internet, or other digital communication network. The data network 106 may include two or more networks. The data network 106 may include one or more servers, routers, switches, and/or other networking equipment. The data network 106 may also include one or more computer readable storage media, such as a hard disk drive, an optical drive, non-volatile memory, RAM, or the like.

The differentiable machine module 104, in some embodiments, may be configured to use a learning algorithm for setting the parameters of a differentiable machine 110 and/or an associated differentiable model to minimize an error function, or the like. The differentiable machine module 104, in a further embodiment, may be configured to use automatic differentiation or another backpropagation process to perform the chain rule or other derivative calculation automatically on multiple differentiable models of a differentiable machine 110 (e.g., in order to tune and/or set or adjust weights or other parameters for the differentiable machine 110, or the like).

The differentiable machine module 104, in certain embodiments, may provide one or more user interfaces for a user to select or define a component of a physical system 114, to build and/or test differentiable models and/or differentiable machines 110, or the like, such as a library of components selectable in a user interface, a graphical user interface (“GUI”) depicted on an electronic display screen of a hardware computing device 102, a command line interface (“CLI”), an application programming interface (“API”), a script interface, or the like. In some embodiments, the differentiable machine module 104 may support a differentiable programming language, to adapt or transform other, non-differentiable models into a differentiable form, or the like.

The differentiable machine module 104 may programmatically model components of a physical system 114 as a function, for example:

outputsₜ=M(θ, inputs_{1:t}) (Equation 1)

In Equation 1, in some embodiments, θ represents the configuration parameters governing the differentiable model M and outputsₜ and inputsₜ are the machine outputs and inputs at time t. For example, the differentiable machine module 104 may model a simple physical system 114, such as pulleys, using force multipliers, modeling a single pulley using the equation F=mgh, a doubled pulley with an added multiplier using the equation F=2 mgh, or a quadrupled pulley using the equation F=4 mgh, where m is mass, g is gravity, and h is height. A differentiable machine 110, tuned to outputs 112 of a specific instance of a pulley physical system 114, may be used to solve for parameters such as the length that a pulley has to be drawn, to design a geometry for pulley layout to lift a desired weight with a desired about of force/rope, or the like.

The differentiable machine module 104, in some embodiments, may adapt a physics-based model (e.g., associated with a physical property of a physical system 114 or a component thereof) into a differentiable model. For example, the differentiable machine module 104 may model a direct current motor as either field excited or armature excited, or the like.

In certain embodiments, the differentiable machine module 104 may build a differentiable machine 110 for a laser physical system 114 by determining the components of a laser (e.g., a gain medium, a laser pump, a high reflector, an output coupler, and a laser beam, or the like) and determining a differentiable model for each component. The differentiable machine module 104 may combine the determined differentiable models for the components using an integration layer (e.g., by feeding outputs of the differentiable models into the integration layer, or the like) to form a differentiable machine 110.

The one or more inputs and/or parameters of a differentiable machine 110 may include any configurable property of a physical system 114. In the laser example, the inputs and/or parameters may include one or more geometries, type of gain medium, reflector settings, amount of laser pumping energy, or the like. The one or more outputs of a differentiable machine 110 may include a physical, measurable event, property, outcome, signal, occurrence, or the like, and may match, predict, and/or be tuned with an output 112 of an instance of a physical system 114. For example, if the physical system 114 is a laser, an output of the associated differentiable machine 110 may include one or more of a laser wavelength, frequency, amplitude, coherence, beam intensity, duration, power, an image or video of the laser beam, a vector with several of the aforementioned outputs, or the like. A differentiable machine 110 (e.g., an integration layer and a plurality of differentiable models) may map inputs and/or parameters to one or more outputs.

The differentiable machine module 104 may take the gradient or derivative of a differentiable machine 110 with regard to its inputs and/or parameters, to determine a sensitivity estimate of how changes in the inputs and/or parameters affect the output. The differentiable machine module 104 may pair the gradient or derivative with one or more gradient descent algorithms to determine values for inputs and/or parameters that better match outputs 112 of the actual instance of the physical system 114, or the like.

The differentiable machine module 104 (or a portion thereof executing on a hardware computing device 102, in communication with a hardware computing device 102 over a data network 106, or the like) may tune and/or train a differentiable machine 110 to a specific, actual instance of a physical system 114. For example, the differentiable machine module 104 may generate and/or determine a generic or default differentiable machine 110 for a type or class of physical system 114, deploy it to several different actual, physical instances or versions of the physical system 114 (e.g., in different geographic locations, or the like), and tune and/or train each of the deployed differentiable machine module 104 based on the different measured outputs 112 of the different instances of the physical system 114.

The differentiable machine module 104 (or a portion thereof executing on a hardware computing device 102, in communication with a hardware computing device 102 over a data network 106, or the like) may determine an output 112 of an instance of a physical system 114 by receiving it from the physical system 114 and/or by measuring and/or detecting the output 112 using a sensor (e.g., a camera or other optical sensor, a microphone, a thermometer, a barometer, a speedometer, a radar, a lidar, a scale, an accelerometer, a motion sensor, an infrared sensor, a medical sensor, or the like). The differentiable machine module 104 may use machine learning or other artificial intelligence to tune and/or train a differentiable machine 110 based on outputs 112 from an instance of a physical system 114 (e.g., so one or more outputs of the differentiable machine 110 match or approximate one or more outputs of the instance of the physical system 114, or the like).

In certain embodiments, the differentiable machine module 104 may combine several differentiable machines 110 as models or subcomponents of a larger differentiable machine 110 or group of differentiable machines 110. For example, in the laser example above, the differentiable machine module 104 may use the modeled laser differentiable machine 110 together with additional components (e.g., a focusing lens, a jet, an interference mirror, a photodiode, a waveguide, an isolator, a tuner, a source gas, a substrate, power, or the like) to generate a differentiable machine 110 for a plasma generation device (e.g., a microwave plasma generator or the like) that uses laser bursts to turn Xenon gas into a plasma. In a further embodiment, the differentiable machine module 104 may combine differentiable machines 110 for various industrial equipment in the same factory or other location, into a larger differentiable machine 110 representing the factory or other location, in a hierarchy of differentiable machines 110, or the like.

Another example of a physical system 114 is a lithography machine. The differentiable machine module 104 may determine that components of a lithography machine include one or more of a plasma generator, a mirror system, a vacuum pump, a tin droplet dispenser, a photoresist dispenser, or the like. The differentiable machine module 104 may determine that a lithography machine has inputs of power, tin, a silicon wafer, or the like and an output 112 of an exposed silicon wafer.

A further example of a physical system 114 is an autonomous vehicle, such as a self-driving automobile, an aircraft with autopilot, a drone, or the like. The differentiable machine module 104 may model the dynamics of a given vehicle to more accurately avoid crashes, or the like. The differentiable machine module 104 may tune a differentiable machine 110 for a vehicle, in some embodiments, with live measurements gathered from the sensors and systems of the vehicle itself. In a further embodiment, the differentiable machine module 104 may deploy the differentiable machine 110 with the vehicle itself, in order to account for history of repairs, traveling, fueling, and the like which may occur at different geographical locations over time.

One more example of a physical system 114 is a genetic sequencing device. The differentiable machine module 104 may determine that components of a genetic sequencing device may include one or more of a genome slicer, a PCR cloning setup, a fragment assembler and aligner, or the like. The differentiable machine module 104 may determine that a genetic sequencing device has an input of a genomic sample, or the like and an output 112 of a digital readout of a genetic sequence.

A further example of a physical system 114 is a biological assay. The differentiable machine module 104 may generate a differentiable machine 110 that accounts for complex factors such as quality of reagents, environmental conditions, vibrations, or the like, which may provide robustness against noise conditions. For example, a microscopy assay may depend on ambient light conditions which can be modeled by a differentiable microscopy differentiable machine 110, or the like.

An additional example of a physical system 114 is a mirror system (e.g., as a sub-component of a laser, a plasma generation device, or the like). The differentiable machine module 104 may determine that components of a mirror system include one or more mirrors, or the like. The differentiable machine module 104 may determine that a mirror system has an input of light, or the like and an output 112 of a light output direction and amplitude

A certain example of a physical system 114 is an X-ray crystallography device. The differentiable machine module 104 may determine that components of an X-ray crystallography device include one or more of an X-ray emitter, a crystallized sample, a shield, a photographic plate, or the like. The differentiable machine module 104 may determine that an X-ray crystallography device has inputs of a sample, power, or the like and an output 112 of a diffraction image.

A further example of a physical system 114 is a cryo-electron microscopy device. The differentiable machine module 104 may determine that components of a cryo-electron microscopy device include one or more of liquid ethane, carbon film, an electron beam generator, a microscope column, or the like. The differentiable machine module 104 may determine that a cryo-electron microscopy device has inputs of liquid ethane, a sample, or the like and an output 112 of exposed film.

One other example of a physical system 114 is a microscope. The differentiable machine module 104 may determine that components of a microscope include one or more of a lens, a stage, a stepper, a light source, a camera, or the like. The differentiable machine module 104 may determine that a microscope has an input of a sample, or the like and an output 112 of a photograph, or the like.

Another example of a physical system 114 is a mass spectrometer. The differentiable machine module 104 may determine that components of a mass spectrometer include one or more of a magnet, an ion source, an electron beam, an insulator, a vacuum pump, a detector, or the like. The differentiable machine module 104 may determine that a mass spectrometer has inputs of a gaseous sample, or the like and an output 112 of a detection signal, or the like.

An additional example of a physical system 114 is a microfluidic device. The differentiable machine module 104 may determine that components of a microfluidic device include one or more of a medium, a syringe pump, a channel structure, a measurement device, or the like. The differentiable machine module 104 may determine that a microfluidic device has inputs of a solution with a sample, or the like and an output 112 of a downstream measurement, or the like.

A further example of a physical system 114 is a silicon foundry. The differentiable machine module 104 may determine that components of a silicon foundry include one or more of an extreme ultraviolet (“EUV”) lithography machine, an etching machine, a wafer cleaning preparation machine, a chip design, or the like. The differentiable machine module 104 may determine that a silicon foundry has inputs of a wafer, a chip design, or the like and an output 112 of a processed chip, or the like. The differentiable machine module 104 may use a differentiable machine 110 of a silicon foundry to control, tune, optimize, predict and/or determine repairs, or the like for the silicon foundry, allowing the differentiable machine module 104 to minimize human interaction and/or entrance into the clean room environment of the silicon foundry.

Like a silicon foundry, in certain embodiments, the differentiable machine module 104 may combine several differentiable machines 110 into a larger group, to represent a factory or other combination of complex physical systems 114. The differentiable machine module 104 may enable improved control of operations and/or efficiency of a factory. For example, a differentiable machine 110 for a silicon or other semiconductor foundry or another type of factory may increase yield rates, enable systematic tunability of operations using differentiable programming, or the like.

In a further embodiment, the differentiable machine module 104 may determine a differentiable machine 110 representing a physical system 114 comprising a biological system, one or more biological cells, a living organism, a combination of a living organism and a medical device, or the like (e.g., for a human, an animal, a plant, or the like). In such an embodiment, at least one of the differentiable models may comprise a pharmacokinetic model (e.g., modeling a movement of a drug or anesthetic agent throughout the body), a pharmacodynamic model (e.g., modeling the intensity and/or time-course of drug effects on the body), a metabolite handling model (e.g., modeling metabolic pathways and/or reactions of one or more cells), or the like. The differentiable machine module 104 may determine outputs 112 of the biological physical system 114 such as a blood panel, a questionnaire, a photo and/or video, a heart rate, a cat scan, a magnetic resonance imaging (“MRI”) scan, a checkup by a doctor, or the like.

In certain embodiments, the differentiable machine module 104 may determine a differentiable model for a component of a physical system 114 by converting the component into an embedding vector, which is unique in a high dimensional space in a way that is amenable to rapid queries, or the like. The differentiable machine module 104, in a further embodiment, may select a differentiable model that approximates a physical property of at least one of the components of the physical system 114, such as gravity, Ohm's law, one or more of Newton's laws of motion, inertia, Coulomb's law, the law of conservation of energy or of momentum, the first or second law of thermodynamics, or the like. As described above, the differentiable machine module 104 and/or a user may select a differentiable model from a library of predefined components, based on known physical properties, devices, machines, and/or other components and their properties.

Instead of or in addition to using a differentiable machine 110 to monitor, control, adjust, repair, troubleshoot, or otherwise manage an instance of a physical system 114 (e.g., over time, over the lifetime of the physical system 114, or the like), in some embodiments, the differentiable machine module 104 may use a differentiable machine 110 for rapid prototyping of versions of the physical system 114. For example, the differentiable machine module 104 may enable a user to iteratively update parameters of a differentiable machine 110 based on one or more outputs of an instance of a physical system 114 and to update one or more aspects of the instance of the physical system 114 based on one or more outputs of the differentiable machine 110, iteratively repeating the process until a design and/or functionality of the instance of the physical system 114 is satisfactory, or the like.

The differentiable machine module 104 and/or a user may update an aspect of an instance of a physical system 114 by changing a property of the instance of the physical system 114 (e.g., changing a geometry or shape, changing an input, changing an output, changing a material, changing a component, adding a component, removing a component, or otherwise adjusting or manipulating the same instance of the physical system 114) and/or by replacing the instance of the physical system 114 with a new version comprising a different property than the replaced instance of the physical system 114 (e.g., a new prototype, a new sample, a new design, or the like). In some embodiments, the differentiable machine module 104 may automatically test multiple variations of the differentiable machine 110 (e.g., tens, hundreds, thousands, millions) to optimize tuning of parameters for the differentiable machine 110, or the like. Using a differentiable machine 110 as part of an iterative prototyping process may reduce the number of physical design iterations, improve the quality of the resulting physical system 114, reduce errors, or the like.

In other embodiments, the differentiable machine module 104 may deploy (e.g., send, install, download, ship, or the like) differentiable machines 110 to instances of physical systems 114 of different customers, different geographic locations, or the like (e.g., a fleet of physical systems 114, each product sold, and/or another group of physical systems 114). The differentiable machine module 104 may use the different differentiable machines 110, each tuned, trained, and/or customized to different instances of the physical system 114, to manage the different instances over time based on outputs of the differentiable machines 110, or the like (e.g., to predict repairs, to optimize settings or other parameters, to correct errors, to detect the need for maintenance and/or replacement, to tune performance, to assist with customer service, and/or otherwise manage the different instances of the physical system 114).

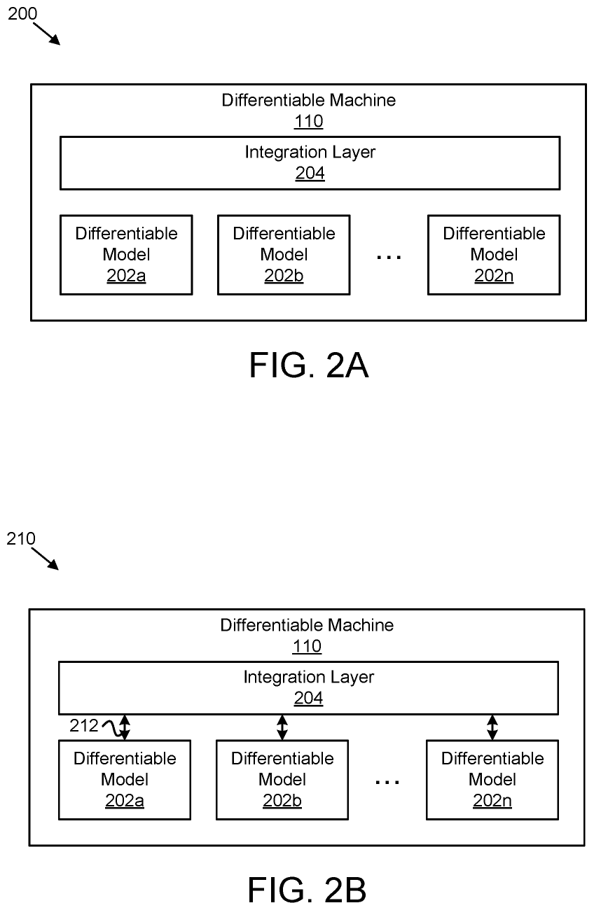

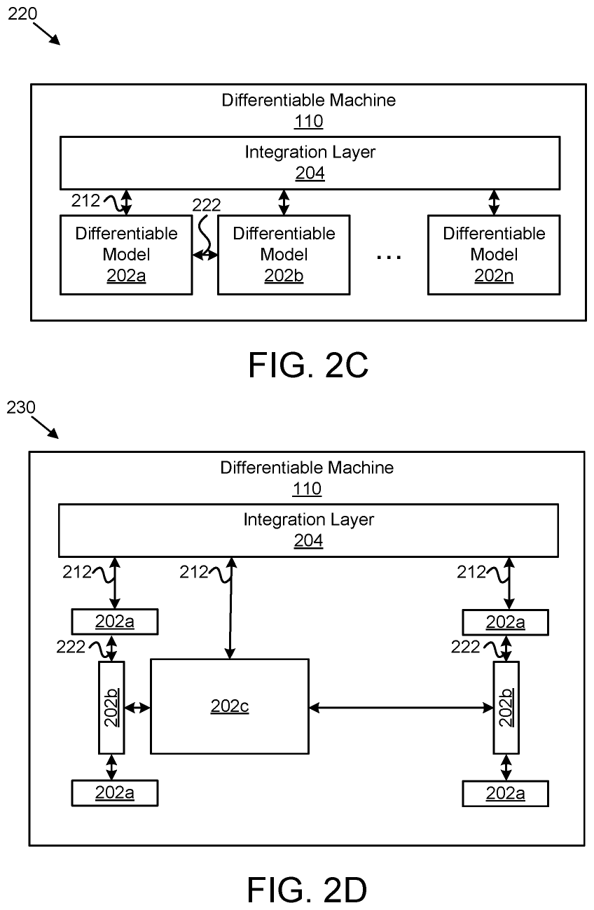

FIG. 2A depicts one embodiment 200 of a differentiable machine 110. In the depicted embodiment 200, the differentiable machine 110 includes an integration layer 204 and a plurality of differentiable models 202a-n. The integration layer 204, in certain embodiments, may combine outputs of the differentiable models 202a-n, provide inputs to the differentiable models 202a-n, route communications between differentiable models 202a-n, approximate one or more attributes of missing and/or unknown differentiable models 202 for associated components of a physical system 114, or the like (e.g., based on one or more outputs of other differentiable models 202a-n, based on outputs 112 of an instance of the physical system 114, or the like). The integration layer 204, in one embodiment, may weigh and/or scale inputs and/or outputs of the differentiable models 202a-n, in order to tune or otherwise adjust the differentiable machine 110.

In some embodiments, the integration layer 204 and/or one or more of the differentiable models 202a-n, may comprise machine learning and/or other artificial intelligence (e.g., to train on outputs 112 of an instance of a physical system 114, or the like). For example, an integration layer 204 and/or a differentiable model 202a-n may comprise a neural network, a fully connected network, a graph network, a long short-term memory (“LSTM”) network, a recurrent neural network (“RNN”), an equivariant network, a convolutional network, a universal approximator, or the like.

FIG. 2B depicts another embodiment 210 of a differentiable machine 110. In the depicted embodiment 210, the differentiable machine module 104 has arranged the differentiable models 202a-n linearly, combining outputs 212 of the differentiable models 202a-n using the integration layer 204. For example, the integration layer 204 may sum outputs 212 of the differentiable models 202a-n, may using a voting algorithm, and/or may otherwise combine the outputs 212 of the differentiable models 202a-n.

FIG. 2C depicts a certain embodiment 220 of a differentiable machine 110. In the depicted embodiment, the differentiable machine module 104 has arranged the differentiable models 202a-n in a pairwise configuration, with communication 222 between the differentiable models 202a-n. For example, the communication 222 between the differentiable models 202a-n may be configured in a feedback loop, a daisy chain, a control group, and/or other structure and arrangement of the differentiable models 202a-n.

FIG. 2D depicts a further embodiment 230 of a differentiable machine 110. In the depicted embodiment, the differentiable machine module 104 has arranged the differentiable models 202a-n in a graph configuration, with communication connections 222 between differentiable models 202a-c determined based on a physical arrangement of the associated components of the physical system 114 the differentiable machine 110 represents. In one embodiment, the differentiable machine module 104 may provide communication connections 222 between closest neighboring differentiable models 202a-c, or the like.

In a further embodiment, the differentiable machine module 104 provides communication connections 222 between differentiable models 202a-c based on a blueprint, map, image, and/or other representation of the physical system 114 and its components, so that the differentiable machine 110 more closely resembles the physical system 114, or the like. For example, in the depicted embodiment 230, the differentiable machine 110 may represent a physical system 114 comprising an automobile or other vehicle, and the differentiable machine module 104 may arrange the differentiable models 202a-c as wheels 202a, axels 202b, and an engine 202c. Other embodiments may be more complex, with more granular components represented by additional differentiable models 202a-n, more complex interconnections 222, or the like. In certain embodiments, the differentiable machine module 104 may provide a user interface allowing a user to submit a representation of a physical system 114 (e.g., using a graphical computer-aided drafting tool, an API, a CLI, a scripting interface, a file transfer interface, or the like).

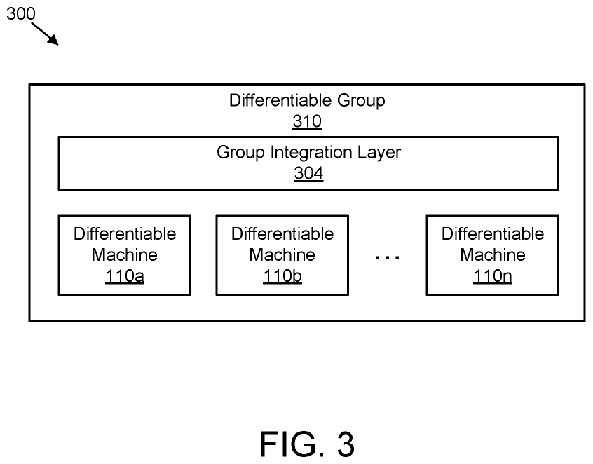

FIG. 3 depicts one embodiment 300 of a differentiable group 310. In the depicted embodiment 300, the differentiable machine module 104 has determined a plurality of differentiable machines 110a-n (e.g., with their own differentiable models 202a-n and integration layers 204, or the like) each representing different physical systems 114, and has combined the plurality of differentiable machines 110a-n using a group integration layer 304 to form a differentiable group 310. For example, the differentiable machines 110a-n may be components of a silicon or other semiconductor foundry and/or of another factory, and the differentiable group 310 may allow the entire foundry and/or factory to be managed, controlled, and/or optimized as a group, in a similar manner to managing a single physical system 114 using a differentiable machine 110.

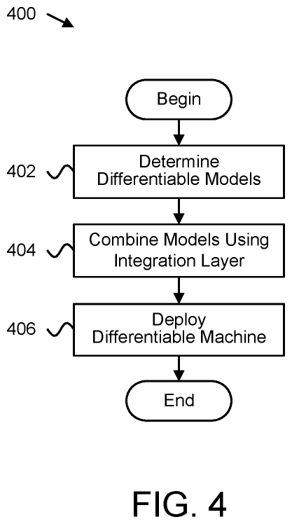

FIG. 4 depicts one embodiment of a method 400 for a differentiable machine 110 for a physical system 114. The method 400 begins and a differentiable machine module 104 and/or a hardware server device 108 determines 402 a plurality of differentiable models 202a-n, each of the differentiable models 202a-n representing a component of a physical system 114. The differentiable machine module 104 and/or the hardware server device 108 combines 404 the plurality of differentiable models 202a-n using an integration layer 204 so that the integration layer 204 and the combined differentiable models 202a-n form a differentiable machine 110 representing the physical system 114. The differentiable machine module 104 and/or the hardware server device 108 deploys 406 the differentiable machine 110 for an instance of the physical system 114 and the method 400 ends.

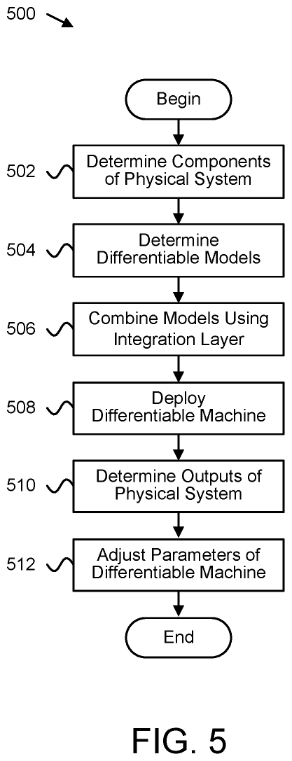

FIG. 5 depicts one embodiment of a method 500 for a differentiable machine 110 for a physical system 114. The method 500 begins and a differentiable machine module 104 and/or a hardware server device 108 determines 502 components of a physical system 114. The differentiable machine module 104 and/or the hardware server device 108 determines 504 a plurality of differentiable models 202a-n, each of the differentiable models 202a-n representing a component of the physical system 114.

The differentiable machine module 104 and/or the hardware server device 108 combines 506 the plurality of differentiable models 202a-n using an integration layer 204 so that the integration layer 204 and the combined differentiable models 202a-n form a differentiable machine 110 representing the physical system 114. The differentiable machine module 104 and/or the hardware server device 108 deploys 508 the differentiable machine 110 for an instance of the physical system 114.

A hardware computing device 102 and/or the differentiable machine module 104 determine 510 one or more outputs 112 of the instance of the physical system 114. The hardware computing device 102 and/or the differentiable machine module 104 adjust 512 one or more parameters of the differentiable machine 110 based on the one or more outputs 112 and the method 500 ends.

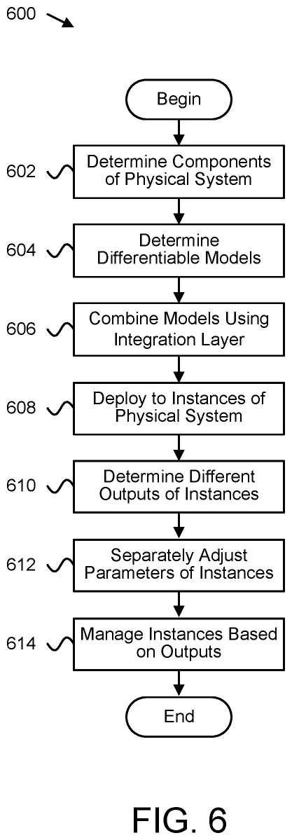

FIG. 6 depicts one embodiment of a method 600 for a differentiable machine 110 for a physical system 114. The method 600 begins and a differentiable machine module 104 and/or a hardware server device 108 determines 602 components of a physical system 114. The differentiable machine module 104 and/or the hardware server device 108 determines 604 a plurality of differentiable models 202a-n, each of the differentiable models 202a-n representing a component of the physical system 114.

The differentiable machine module 104 and/or the hardware server device 108 combines 606 the plurality of differentiable models 202a-n using an integration layer 204 so that the integration layer 204 and the combined differentiable models 202a-n form a differentiable machine 110 representing the physical system 114. The differentiable machine module 104 and/or the hardware server device 108 deploys 608 the differentiable machine 110 to different hardware computing devices 102 for a plurality of different instances of the physical system 114.

The different hardware computing devices 102 and/or one or more differentiable machine modules 104 determine 610 different outputs 112 of the different instances of the physical system 114. The different hardware computing devices 102 and/or one or more differentiable machine modules 104 separately adjust 612 one or more parameters of the differentiable machines 110 for each of the different instances of the physical system 114 based on the different outputs 112. The different hardware computing devices 102 and/or one or more differentiable machine modules 104 manage 614 the different instances of the physical system 114 over time based on outputs of the differentiable machines 110 for each of the different instances of the physical system 114 and the method 600 ends.

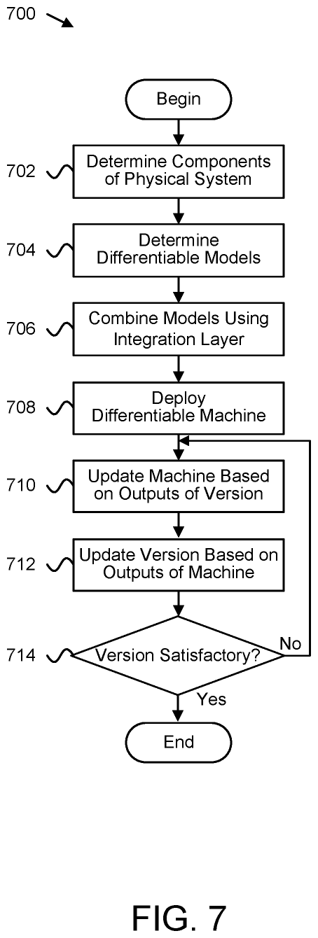

FIG. 7 depicts one embodiment of a method 700 for a differentiable machine 110 for a physical system 114. The method 700 begins and a differentiable machine module 104 and/or a hardware server device 108 determines 702 components of a physical system 114. The differentiable machine module 104 and/or the hardware server device 108 determines 704 a plurality of differentiable models 202a-n, each of the differentiable models 202a-n representing a component of the physical system 114.

The differentiable machine module 104 and/or the hardware server device 108 combines 706 the plurality of differentiable models 202a-n using an integration layer 204 so that the integration layer 204 and the combined differentiable models 202a-n form a differentiable machine 110 representing the physical system 114. The differentiable machine module 104 and/or the hardware server device 108 deploys 708 the differentiable machine 110 for an instance of the physical system 114.

A hardware computing device 102 and/or the differentiable machine module 104 iteratively updates 710 one or more parameters of the differentiable machine 110 based on one or more outputs 112 of the instance of the physical system 114 and updates 712 one or more aspects of the instance of the physical system 114 based on one or more outputs of the differentiable machine 110. The hardware computing device 102 and/or the differentiable machine module 104 determines 714 whether or not the updated version of the instance of the physical system 114 is satisfactory (e.g., satisfies a threshold, satisfies a minimum viability, is deemed satisfactory by one or more users, or the like). If the updated version of the instance of the physical system 114 is satisfactory, the method 700 ends. If the updated version of the instance of the physical system 114 is not yet satisfactory, the iterative updating 710, 712 continues until a subsequently updated 712 version of the instance of the physical system 114 is determined 714 to be satisfactory and the method 700 ends.

A means for determining a plurality of differentiable models 202 each representing a component of a physical system 114, in various embodiments, may include one or more of a hardware computing device 102, a hardware server device 108, a differentiable machine module 104, a processor, a CPU, a processor core, an FPGA, other programmable logic, an ASIC, a controller, a microcontroller, a semiconductor integrated circuit device, and/or another hardware device or other computer executable code stored in a non-transitory computer readable storage medium. Other embodiments may comprise similar or equivalent means for determining a plurality of differentiable models 202 each representing a component of a physical system 114.

A means for combining a plurality of differentiable models 202 using an integration layer 204 so that the integration layer 204 and the combined differentiable models 202 form a differentiable machine 110 representing a physical system 114, in various embodiments, may include one or more of a hardware computing device 102, a hardware server device 108, a differentiable machine module 104, a processor, a CPU, a processor core, an FPGA, other programmable logic, an ASIC, a controller, a microcontroller, a semiconductor integrated circuit device, and/or another hardware device or other computer executable code stored in a non-transitory computer readable storage medium. Other embodiments may comprise similar or equivalent means for combining a plurality of differentiable models 202 using an integration layer 204 so that the integration layer 204 and the combined differentiable models 202 form a differentiable machine 110 representing a physical system 114.

A means for deploying a differentiable machine 110 for an instance of a physical system 114, in various embodiments, may include one or more of a hardware computing device 102, a hardware server device 108, a differentiable machine module 104, a data network 106, a processor, a CPU, a processor core, an FPGA, other programmable logic, an ASIC, a controller, a microcontroller, a semiconductor integrated circuit device, and/or another hardware device or other computer executable code stored in a non-transitory computer readable storage medium. Other embodiments may comprise similar or equivalent means for deploying a differentiable machine 110 for an instance of a physical system 114.

A means for determining one or more outputs 112 of an instance of a physical system 114, in various embodiments, may include one or more of a hardware computing device 102, a hardware server device 108, a differentiable machine module 104, a data network 106, a sensor, a camera or other optical sensor, a microphone, a thermometer, a barometer, a speedometer, a radar, a lidar, a scale, an accelerometer, a motion sensor, an infrared sensor, a medical sensor, a processor, a CPU, a processor core, an FPGA, other programmable logic, an ASIC, a controller, a microcontroller, a semiconductor integrated circuit device, and/or another hardware device or other computer executable code stored in a non-transitory computer readable storage medium. Other embodiments may comprise similar or equivalent means for determining one or more outputs 112 of an instance of a physical system 114.

A means for adjusting one or more parameters of a differentiable machine 110 based on one or more outputs 112, in various embodiments, may include one or more of a hardware computing device 102, a hardware server device 108, a differentiable machine module 104, a processor, a CPU, a processor core, an FPGA, other programmable logic, an ASIC, a controller, a microcontroller, a semiconductor integrated circuit device, and/or another hardware device or other computer executable code stored in a non-transitory computer readable storage medium. Other embodiments may comprise similar or equivalent means for adjusting one or more parameters of a differentiable machine 110 based on one or more outputs 112.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. An apparatus comprising:
a hardware server device configured to:
determine a plurality of differentiable models, each of the differentiable models representing a component of a physical system;
combine the plurality of differentiable models using an integration layer such that the integration layer and the combined differentiable models form a differentiable machine representing the physical system; and
deploy the differentiable machine for an instance of the physical system.

2. The apparatus of claim 1, further comprising a hardware computing device in communication with the instance of the physical system, the hardware computing device configured to:
determine one or more outputs of the instance of the physical system; and
adjust one or more parameters of the differentiable machine based on the one or more outputs.

3. The apparatus of claim 2, wherein the one or more parameters of the differentiable machine comprise weights for the differentiable models.

4. The apparatus of claim 2, further comprising a plurality of different hardware computing devices in communication with a plurality of different instances of the physical system, wherein:
the hardware server device is further configured to deploy the differentiable machine to each of the different hardware computing devices; and
the different hardware computing devices are configured to:
determine different outputs of the different instances of the physical system; and
separately adjust one or more parameters of the differentiable machines for each of the different instances of the physical system based on the different outputs.

5. The apparatus of claim 4, wherein the hardware server device is further configured to manage the different instances of the physical system over time based on outputs of the differentiable machines for each of the different instances of the physical system.

6. The apparatus of claim 1, wherein the hardware server device is further configured to prototype versions of the physical system by iteratively:
updating one or more parameters of the differentiable machine based on one or more outputs of the instance of the physical system; and
updating one or more aspects of the instance of the physical system based on one or more outputs of the differentiable machine.

7. The apparatus of claim 6, wherein updating the one or more aspects of the instance of the physical system comprises one or more of changing a property of the instance of the physical system and replacing the instance of the physical system with a new version of the instance of the physical system, the new version comprising a different property than the replaced instance of the physical system.

8. The apparatus of claim 1, wherein each differentiable model comprises a domain and a derivative exists at each point in the domains for the differentiable models such that the differentiable machine is differentiable end-to-end.

9. The apparatus of claim 1, wherein the hardware server device is further configured to:
determine a plurality of differentiable machines, each of the differentiable machines representing different physical systems; and
combine the plurality of differentiable systems using a group integration layer such that the group integration layer and the combined differentiable machines form a differentiable group.

10. The apparatus of claim 1, wherein the hardware server device is configured to determine the plurality of differentiable models based on user input selecting one or more of the plurality of differentiable models from a library of components selectable using a user interface.

11. The apparatus of claim 1, wherein the hardware server device combines the plurality of differentiable models linearly combining outputs of the differentiable models using the integration layer.

12. The apparatus of claim 1, wherein the hardware server device combines the plurality of differentiable models in a pairwise configuration with communication between the differentiable models.

13. The apparatus of claim 1, wherein the hardware server device combines the plurality of differentiable models in a graph configuration with communication connections between the differentiable models determined based on a physical arrangement of the components of the physical system.

14. The apparatus of claim 1, wherein the physical system comprises one or more of:
a laser device;
a plasma generation device;
a pulley system;
a mirror system;
a lithography machine;
a motor;
an autonomous vehicle;
a silicon foundry;
a medical device;
a genetic sequencing device;
an X-ray crystallography device;
a cryo-electron microscopy device;
a cryo-tomography device;
a microscope device;
a mass spectrometry device; and
a microfluidic device.

15. The apparatus of claim 1, wherein the physical system comprises one or more of, a biological system, one or more biological cells, a living organism, and a combination of a living organism and a medical device, and at least one of the differentiable models comprises one or more of a pharmacokinetic model, a pharmacodynamic model, and a metabolite handling model.

16. The apparatus of claim 1, wherein at least one of the differentiable models comprises an approximator model configured to approximate one or more attributes of at least one of the components of the physical system based on one or more outputs of the differentiable models and the instance of the physical system.

17. The apparatus of claim 1, wherein the integration layer comprises a neural net configured to determine an arrangement for the differentiable models in the combination based on one or more outputs of the differentiable models and the instance of the physical system.

18. The apparatus of claim 1, wherein at least one of the differentiable models approximates a physical property of at least one of the components of the physical system.

19. A computer program product comprising executable program code stored on a non-transitory computer readable storage medium, the executable program code executable by a processor to perform operations, the operations comprising:
determining a plurality of differentiable models, each of the differentiable models representing a component of a physical system;
combining the plurality of differentiable models using an integration layer such that the integration layer and the combined differentiable models form a differentiable machine representing the physical system; and
deploying the differentiable machine for an instance of the physical system.

20. The computer program product of claim 19, wherein the operations further comprise:
determining one or more outputs of the instance of the physical system; and
adjusting one or more parameters of the differentiable machine based on the one or more outputs.

21. The computer program product of claim 20, wherein the operations further comprise one or more of:
managing the instance of the physical system over time based on one or more outputs of the differentiable machine; and
prototyping versions of the physical system by iteratively updating one or more parameters of the differentiable machine based on one or more outputs of the instance of the physical system and updating one or more aspects of the instance of the physical system based on one or more outputs of the differentiable machine.

22. An apparatus comprising:
means for determining a plurality of differentiable models, each of the differentiable models representing a component of a physical system;
means for combining the plurality of differentiable models using an integration layer such that the integration layer and the combined differentiable models form a differentiable machine representing the physical system; and
means for deploying the differentiable machine for an instance of the physical system.

23. The apparatus of claim 22, further comprising:
means for determining one or more outputs of the instance of the physical system; and
means for adjusting one or more parameters of the differentiable machine based on the one or more outputs.
